(19) United States
(12) Patent Application Publication
(10) Pub. No.: US 2002/0015917 A1
(43) Pub. Date: Feb. 7, 2002

(54) Multi-oxygen containing compound for preventing acid diffusion, and photoresist composition containing the same

(76) Inventors: Geun Su Lee, Kyoungki-do (KR); Jae Chang Jung, Kyoungki-do (KR); Min Ho Jung, Kyoungki-do (KR); Cheol Kyu Bok, Kyoungki-do (KR); Ki Ho Baik, Kyoungki-do (KR)

Correspondence Address: TOWNSEND AND TOWNSEND AND CREW, TWO EMBARCADERO CENTER, EIGHTH FLOOR, SAN FRANCISCO, CA, 94111-3834, US

(21) Appl. No.: 09/881,562

(22) Filed: Jun. 13, 2001

Related U.S. Application Data
(63) Continuation-in-part of application No. 09/465,526, filed on Dec. 16, 1999, now abandoned.

(30) Foreign Application Priority Data
Dec. 31, 1998 (KR) 98-63790

(51) Int. Cl. G03F 7/038; G03F 7/38; G03F 7/40; G03F 7/20

(52) U.S. Cl. 430/281.1; 430/270.1; 430/296; 430/330; 430/327; 430/311; 430/280.1; 430/320; 430/328; 430/905; 430/913; 528/9; 528/395

(57) ABSTRACT

The present invention relates to a compound for preventing the acid generated during the exposure step of a photolithography process in the exposed areas, from being diffused to the unexposed areas, and a process for forming an ultra-micro pattern using the same.

In accordance with a preferred embodiment of the present invention, a multi-oxygen-containing compound such as a crown ether derivative or a polyethylene glycol derivative is used as the compound to prevent such acid diffusion.

### CROSS-REFERENCES TO RELATED APPLICATIONS

This application is a continuation-in-part of U.S. patent application Ser. No. 09/465,526 filed Dec. 16, 1999, which claims priority from Korean Patent Application No. 98-63790, filed Dec. 31, 1998, which are incorporated herein by reference in their entirety.

### FIELD OF THE INVENTION

The present invention relates to an additive for preventing acid diffusion in a photolithography process, a photoresist composition comprising the same, and a process for forming a photoresist micro-pattern. More specifically, the present invention relates to a multi-oxygen containing compound for preventing the acid generated in the exposed area during the course of a photolithography process from being diffused to the unexposed area, and a process for forming an ultra-micro pattern using the same.

### BACKGROUND OF THE INVENTION

Recently, chemical amplification-type DUV (deep ultra violet) photoresists have proven to be useful to achieve high sensitivity in processes for preparing micro-circuits in the manufacture of semiconductors. These photoresists are prepared by blending a photoacid generator with polymer matrix macromolecules having acid labile structures.

According to the reaction mechanism of such a photoresist, the photoacid generator generates acid when it is irradiated by the light source, and the main chain or branched chain of the polymer matrix in the exposed portion is reacted with the generated acid to be decomposed or cross-linked, so that the polarity of the polymer is considerably altered. This alteration of polarity results in a solubility difference in the developing solution between the exposed area and the unexposed area, thereby forming a positive or negative image of a mask on the substrate.

However, it has been observed that some of the acid generated in the exposed area is diffused to the unexposed area during the course of exposure or the post exposure delay (PED) stage to damage the pattern in the unexposed area.

In order to prevent the acid diffusion described above, a weak basic amine or amide compound, which can combine with the generated acid, has been conventionally added to a chemical amplification type photoresist composition to prevent the acid generated in the exposed area from being diffused to the unexposed area.

However, such an amine or amide compound has high light absorbance in the extremely short wave region of 250 nm or less, for example in the wavelength region of ArF (193 nm), to deteriorate the sensitivity of a photoresist composition.

### BRIEF SUMMARY OF THE INVENTION

The object of the present invention is to solve the problems of the conventional technique as described above, and to provide a substance which can effectively prevent diffusion of acid generated from the exposed area and shows low light absorbance in the extremely short wavelength region of the light spectrum.

Another object of the present invention is to provide a process for forming a micro-pattern having excellent profile in a lithography process employing a light source of extremely short wavelength of not more than 250 nm, by using the substance for preventing acid diffusion.

In order to achieve these objects, the present invention provides multi-oxygen containing compounds.

The present invention also provides a photoresist composition comprising a multi-oxygen containing compound as an additive for preventing acid diffusion.

Further, it provides a process for forming a photoresist micro-pattern by using the photoresist composition mentioned above.

### BRIEF DESCRIPTION OF THE DRAWINGS

FIG. 1 shows a photoresist pattern obtained from Example 1.

FIG. 2 shows a photoresist pattern obtained from Example 2.

FIG. 3 shows a photoresist pattern obtained from Example 3.

### DETAILED DESCRIPTION OF THE INVENTION

### Multi-oxygen Containing Compound for Preventing Acid Diffusion

The inventors have performed intensive studies to achieve the objects of the invention described above, and have found that multi-oxygen-containing compounds such as a crown ether derivative and a polyethylene glycol derivative, are effective to prevent diffusion of acid generated in the course of exposure during the photolithography process.

The crown ether derivative is preferably selected from the group consisting of the compounds represented by the following Chemical Formulas 1a and 1b; and the polyethylene glycol derivative is represented by the following Chemical Formula 1c:

### Chemical Formulas 1a

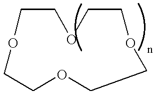

wherein, n represents a number from 1 to 5.

### Chemical Formulas 1b

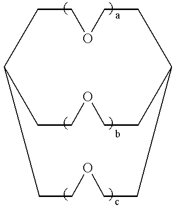

wherein, a, b and c individually represent a number from 1 to 5.

### Chemical Formulas 1c

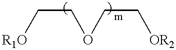

wherein, R1 and R2 individually represent hydrogen, straight or branched C1-10 alkyl including at least one hydroxyl group, straight or branched C1-10 ester including at least one hydroxyl group, straight or branched C1-10 ketone including at least one hydroxyl group, straight or branched C1-10 carboxylic acid including at least one hydroxyl group, and straight or branched C1-10 acetal including at least one hydroxyl group; and m represents a number from 1 to 20.

The preferred multi-oxygen-containing crown ether derivatives include the compounds represented by Chemical Formulas 2 to 8 shown below. However, any type of crown ether compound containing oxygen may be used as a substance for preventing acid diffusion according to the present invention.

1)12-crown-4;

### Chemical Formula 2

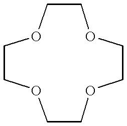

2)15-crown-5;

### Chemical Formula 3

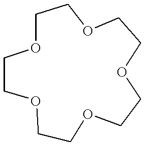

3) 18-crown-6;

<Chemical Formula 4>

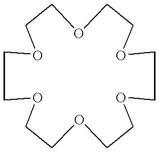

4)[2.2.2]bicyclic crown ether;

### Chemical Formula 5

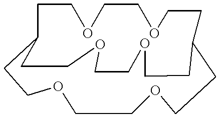

5)[2.2.1]bicyclic crown ether;

### Chemical Formula 6

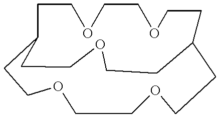

6)[2.1.1]bicyclic crown ether

### Chemical Formula 7

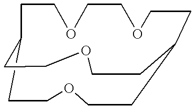

7)[1.1.1]bicyclic crown ether

### Chemical Formula 8

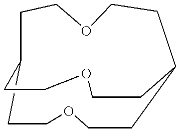

Most oxygen-containing compounds such as alcohol or ether have very weak basicity. However, as opposed to general ether compounds, crown ether compounds show strong basicity because several oxygens are regularly arranged in a crown ether molecule, and their lone electron pairs are concentrated in a narrow space to show a cooperative effect.

Thus, the cyclic structure of the crown ether can serve as a base to collect acid generated in the exposed area. Accordingly, the compound collects acid which has diffused to the unexposed area, thereby preventing surface damage of the pattern in the unexposed area during the succeeding developing stage.

Further, a compound having a crown ether moiety generally has an excellent ability to transport acids or cations. Thus, the compound not only collects acid in the unexposed area, but also transports and releases the collected acid to the exposed area, to further increase the photosensitivity of the photoresist composition.

The polyethylene glycol compounds, which have the same function as the crown ether, include the following compounds, wherein n is the number of repeating units to achieve the indicated molecular weights:

1) poly(ethylene glycol);

H(OCH2CH2)nOH/distribution of molecular weight: 500-10000

2) poly(ethylene glycol)bis(carboxymethyl)ether;

HO2CCH2(OCH2CH2)nOCH2CO2H/distribution of molecular weight: 200-2000

3) poly(ethylene glycol)dimethyl ether;

CH₃(OCH₂CH₂)ₙOCH₃/distribution of molecular weight: 200-2000

4) poly(ethylene glycol)methyl ether;

CH₃(OCH₂CH₂)ₙOH/distribution of molecular weight: 200-2000

At the same time, the multi-oxygen-containing crown ethers and polyethylene glycol compounds, in contrast to the conventional amine or amide substances for preventing acid diffusion, have low absorbance of light with extremely short wavelengths of 250 nm or less. Therefore, the photosensitivity of a photoresist composition containing said compounds will not be deteriorated.

In addition, due to the fact that crown ether compounds are used as a phase-transfer catalyst between an organic layer and an aqueous layer, the compounds contribute to enhance adhesiveness between the organic layer and the aqueous layer. Thus, the adhesiveness between a substrate and a photoresist pattern of a semi-conductor element can be enhanced when the multi-oxygen containing compounds of the present invention are used as an additive for a photoresist.

### Preparation of Photoresist Compositions and Formation of Micro- patterns

The photoresist composition according to the present invention may be prepared by adding a compound for preventing acid diffusion according to the present invention to a conventional photoresist composition. In particular, the compound for preventing acid diffusion according to the present invention is suitably used in a lithography process employing a photo-amplification type photoresist composition and a light source of extremely short wavelength, i.e., 250 nm or less.

The photoresist composition according to the present invention comprises (i) photoresist polymer, (ii) photoacid generator, (iii) multi-oxygen containing compound for preventing acid diffusion according to the present invention, and (iv) an organic solvent. The process for preparing the composition is described below in more detail with reference to a preferred embodiment.

First, a conventional photoresist polymer is dissolved in organic solvent, and a photoacid generator and a multi-oxygen containing compound for preventing acid diffusion according to the present invention are added to the solution.

The photoresist polymer, photoacid generator and organic solvent of the photoresist composition can be any currently known one disclosed in U.S. Pat. No. 5,212,043 (May 18, 1993), WO 97/33198 (Sep. 12, 1997), WO 96/37526 (Nov 28, 1996), EP 0 794 458 (Sep. 10, 1997), EP 0789 278 (Aug. 13, 1997) and U.S. Pat. No. 6,132,926 (Oct. 17, 2000).

It is preferable that the PR polymer be prepared by radical addition polymerization of alicyclic comonomers (such as cycloolefin) where the ring structures of the cycloolefin comonomers form the backbone of the PR polymer. An exemplary PR polymer includes poly(tert-butyl bicyclo[2.2.1]hept-5-ene-2-carboxylate/2-hydroxydthyl bicyclo[2.2.1]hept-5-ene-2-carboxylate/bicyclo[2.2.1]hept-5-ene-2-carboxylic acid/maleic anhydride). In addition, PR polymers preferably comprise 2-hydroxydthyl bicyclo[2.2.1]hept-5-ene-2-carboxylate or 2-hydroxydthyl bicyclo[2.2.2]oct-5-ene-2-carboxylate in order to improve adhesiveness to wafer.

As a photoacid generator, sulfide or onium type compound, for example, diphenyl iodide hexafluorophosphate, diphenyl iodide hexafluoroarsenate, diphenyliodide hexafluoroantimonate, diphenyl p-methoxyphenyl triflate, diphenyl p-toluenyl triflate, triphenylsulfonium hexafluorophosphate, triphenylsulfonium hexafluoroarsenate, triphenylsulfonium hexafluoroantimonate, triphenylsulfonium triflate or dibutylnaphthylsulfonium triflate may be used.

As an organic solvent, propylene glycol methyl ether acetate, ethyl 3-ethoxypropionate, methyl 3-methoxypropionate, cyclohexanone, cyclopentanone, or the like may be used.

A process for forming a photoresist pattern by using the photoresist composition thus prepared, is described below:

First, a photoresist composition according to the present invention is spin-coated on a silicon wafer to form a thin photoresist film, which is then “soft-baked” in an oven or on a hot plate at 80° C. to 150° C. for 1 to 5 minutes, and then exposed to patterned light by using a deep ultraviolet exposer or an excimer laser exposer. As the light source, ArF, KrF, VUV, EUV, E-beam, ion beam, x-ray or the like may be used.

Then, the thin photoresist film is “post-baked” at 100° C. to 200° C., and the photoresist film is developed in alkaline developing solution, for example, aqueous TMAH solution, to obtain a micro-pattern of 0.15 μm or less.

By adding the compound for preventing acid diffusion according to the present invention to a photoresist composition, diffusion of acid generated from the exposed area into the unexposed area can be effectively prevented, and adhesiveness of the photoresist pattern to the substrate is enhanced at the same time, thereby providing a photoresist micro pattern having excellent sensitivity.

### EXAMPLE 1

Poly(t-butyl bicyclo[2.2.1]hept-5-ene-2-carboxylate/2-hydroxyethyl bicyclo[2.2.1]hept-5-ene-2-carboxylate/bicyclo[2.2.1]hept-5-ene-2-carboxylic acid/maleic anhydride) as a photoresist copolymer (3.57 g), triphenylsulfonium triflate (0.02 g) as a photoacid generator, and 12-crown-4 of Chemical Formula 2 (0.03 g) were dissolved in ethyl 3-ethoxypropionate solvent (25 g), and the resultant mixture was filtered through a 0.10 μm filter to prepare a photoresist composition.

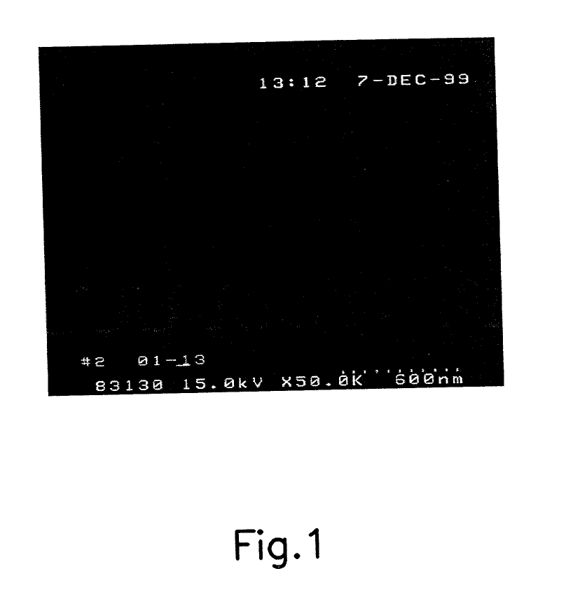

The photoresist composition (1 ml) thus prepared was spin-coated on a silicon wafer, and soft-baked at 110° C. for 90 seconds. After baking, it was exposed to light by using an ArF laser exposer, and post-baked again at 110° C. for 90 seconds. When the post-baking was completed, it was developed in 2.38 wt % aqueous TMAH solution for 40 seconds, to obtain a 0.14 μm L/S pattern (FIG. 1).

EXAMPLE 2

The procedure according to Example 1 was repeated but using [2.2.1]bicyclic crown ether (0.03 g) represented by Chemical Formula 5 instead of 12-crown-4, to prepare a photoresist composition.

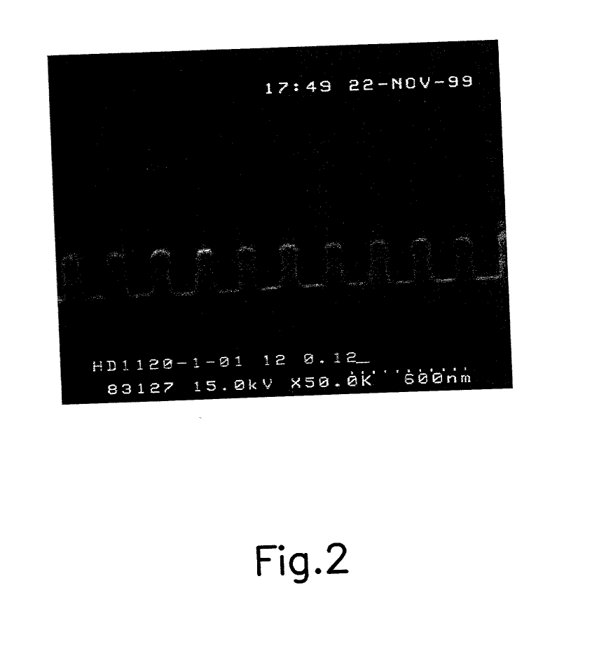

The photolithography procedure of Example 1 was repeated by using the photoresist composition thus prepared, to obtain a 0.14 μm L/S pattern (FIG. 2).

EXAMPLE 3

The procedure according to Example 1 was repeated but using poly(ethylene glycol)bis(carboxymethyl)ether (0.03 g) instead of 12-crown-4, to prepare a photoresist composition.

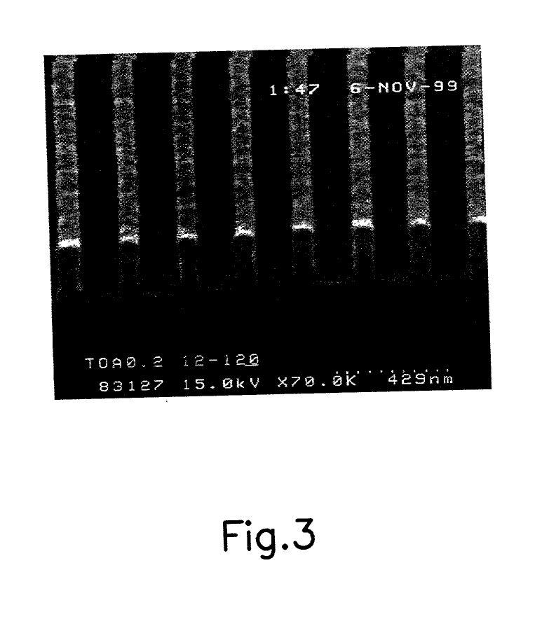

The photolithography procedure of Example 1 was repeated by using the photoresist composition thus prepared, to obtain a 0.12 μm L/S pattern (FIG. 3).

What is claimed is:

1. A photoresist composition for preventing acid diffusion, which comprises (i) a photoresist copolymer derived from alicyclic comonomers, (ii) a photoacid generator, (iii) a multi-oxygen containing compound selected from the group consisting of crown ether and polyethylene derivatives, and (iv) an organic solvent.

2. A photoresist composition of claim 1, wherein the crown ether derivative is selected from the group consisting of the compounds represented by the following Chemical Formulas 1a and 1b; and the polyethylene glycol derivative is represented by the following Chemical Formula 1c: 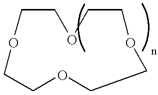
wherein, n represents a number from 1 to 5. 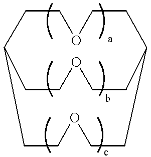
wherein, a, b and c individually represent a number from 1 to 5. 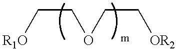
wherein, R₁ and R₂ individually represent hydrogen, straight or branched C₁₋₁₀ alkyl including at least one hydroxyl group, straight or branched C₁₋₁₀ ester including at least one hydroxyl group, straight or branched C₁₋₁₀ ketone including at least one hydroxyl group, straight or branched C₁₋₁₀ carboxylic acid including at least one hydroxyl group, and straight or branched C₁₋₁₀ acetal including at least one hydroxyl group; and m represents a number of 1 to 20.

3. A photoresist composition of claim 2, wherein the crown ether derivative is selected from the group consisting of 12-crown-4, 15-crown-5, 18-crown-6, [2.2.2]bicyclic crown ether, [2.2.1]bicyclic crown ether, [2.1.1]bicyclic crown ether and [1.1.1]bicyclic crown ether.

4. A photoresist composition of claim 2, wherein the polyethylene glycol derivative is selected from the group consisting of poly(ethylene glycol), poly(ethylene glycol)bis(carboxymethyl)ether, poly(ethylene glycol)dimethyl ether and poly(ethylene glycol)methyl ether.

5. A photoresist composition of claim 1, wherein the photoresist polymer is poly(t-butyl bicyclo[2.2.1]hept-5-ene-2-carboxylate/2-hydroxyethyl bicyclo[2.2.1]hept-5-ene-2-carboxylate/bicyclo[2.2.1]hept-5-ene-2-carboxylic acid/maleic anhydride).

6. A photoresist composition of claim 1, wherein the photoacid generator is one or more compound(s) selected from the group consisting of diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, diphenyl p-tert-butylphenyl triflate, triphenylsulfonium hexafluorophosphate, triphenylsulfonium hexafluoroarsenate, triphenylsulfonium hexafluoroantimonate, triphenylsulfonium triflate and dibutylnaphthylsulfonium triflate.

7. A photoresist composition of claim 1, wherein the organic solvent is selected from the group consisting of cyclohexanone, cyclopentanone, methyl 3-methoxypropionate, ethyl 3-ethoxypropionate and propylene glycol methyl ether acetate.

8. A process for forming a photoresist pattern, which comprises the steps of (a) coating the photoresist composition according to claim 1 on a wafer, (b) exposing the wafer to light by employing an exposer, and (c) developing the exposed wafer.

9. A process according to claim 8, which further comprises baking step(s) before and/or after step (b).

10. A process according to claim 9, wherein the baking step(s) are performed at a temperature of 50° C. and 200° C.

11. A process according to claim 8, wherein the light source is selected from the group consisting of ArF, KrF, E-beam, EUV, ion beam and X-ray.

12. A process according to claim 8, wherein the developing step (c) is carried out using an aqueous solution of TMAH (tetramethylammonium hydroxide).

13. A semiconductor element manufactured by using a process according to claim 8.

14. A method for reducing or preventing acid diffusion in a photolithography process comprising adding a multi-oxygen-containing compound to a photoresist composition containing (i) a photoresist polymer, (ii) a photoacid generator and (iii) an organic solvent.

15. The method of claim 14 wherein said multi-oxygen-containing compound is selected from the group consisting of crown ether, poly(ethylene glycol) derivative and mixtures thereof.

16. The method of claim 15 wherein said crown either is selected from the group consisting of: 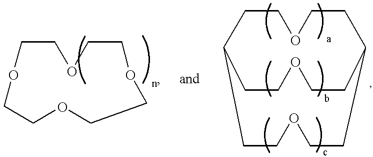
wherein
each of n, a, b, and c is independently an integer from 1 to 5.

17. The method of claim 16, wherein the crown ether derivative is selected from the group consisting of 12-crown-4, 15-crown-5, 18-crown-6, [2.2.2]bicyclic crown ether, [2.2.1]bicyclic crown ether, [2.1.1]bicyclic crown ether and [1.1.1]bicyclic crown ether.

18. The method of claim 15 wherein said poly(ethylene glycol) derivative is selected from the group consisting of: 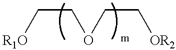
wherein
each of R₁ and R₂ is independently hydrogen, straight or branched C₁₋₁₀ alkyl including at least one hydroxyl group, straight or branched C₁₋₁₀ ester including at least one hydroxyl group, straight or branched C₁₋₁₀ ketone including at least one hydroxyl group, straight or branched C₁₋₁₀ carboxylic acid including at least one hydroxyl group, or straight or branched C₁₋₁₀ acetal including at least one hydroxyl group; and
m is an integer of 1 to 20.

19. The method of claim 18, wherein the polyethylene glycol derivative is selected from the group consisting of poly(ethylene glycol), poly(ethylene glycol)bis(carboxymethyl)ether, poly(ethylene glycol)dimethyl ether and poly(ethylene glycol)methyl ether.

20. The method of claim 14, wherein the photoresist polymer is a chemically amplified photoresist polymer derived from polymerization of cycloolefin comonomers.

21. The method of claim 20, wherein the photoresist polymer is poly(t-butyl bicyclo[2.2.1]hept-5-ene-2-carboxylate/2-hydroxyethyl bicyclo[2.2.1]hept-5-ene-2-carboxylate /bicyclo[2.2.1]hept-5-ene-2-carboxylic acid/maleic anhydride).

22. The method of claim 14, wherein the photoacid generator is selected from the group consisting of diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, diphenyl p-tert-butylphenyl triflate, triphenylsulfonium hexafluorophosphate, triphenylsulfonium hexafluoroarsenate, triphenylsulfonium hexafluoroantimonate, triphenylsulfonium triflate, dibutylnaphthylsulfonium triflate, and mixtures thereof.

23. The method of claim 14, wherein the organic solvent is selected from the group consisting of cyclohexanone, cyclopentanone, methyl 3-methoxypropionate, ethyl 3-ethoxypropionate and propylene glycol methyl ether acetate.
